(19) United States
(12) Patent Application Publication
(10) Pub. No.: US 2023/0323772 A1
(43) Pub. Date: Oct. 12, 2023

(54) GENERATING A RESERVOIR PERFORMANCE FORECAST

(71) Applicant: CHEVRON U.S.A. INC., San Ramon, CA (US)

(72) Inventors: Changdong YANG, Sugar Land, TX (US); Jincong HE, Sugar Land, TX (US); Tsubasa ONISHI, Houston, TX (US); Ronglei ZHANG, Houston, TX (US); Yanbin ZHANG, Bellaire, TX (US); Song DU, Katy, TX (US); Zhenzhen WANG, Houston, TX (US); Xiaoyue GUAN, Houston, TX (US); Jianping CHEN, Houston, TX (US); Xian-Huan WEN, Humble, TX (US); Babafemi Anthony OGUNYOMI, Houston, TX (US)

(73) Assignee: CHEVRON U.S.A. INC., San Ramon, CA (US)

(21) Appl. No.: 17/719,022

(22) Filed: Apr. 12, 2022

(51) Int. Cl. E21B 49/08; G06F 30/27

(52) U.S. Cl. CPC E21B 49/087; E21B 2200/20; G06F 30/27

(57) ABSTRACT

Embodiments for generating a reservoir performance forecast are provided. The embodiments may be executed by a computer system. In one embodiment, a method includes obtaining inflow performance relationship data generated from a physics-based subsurface-surface coupled simulation model having a surface, a subsurface, and one or more wells fluidly connecting the subsurface to the surface. The inflow performance relationship data comprises performance data for at least one phase of fluid for each well. The method also includes generating a performance forecast for the reservoir using a subsurface simulator and a surface simulator. The subsurface simulator uses the inflow performance relationship data to represent the subsurface during generation of the performance forecast, and the performance forecast satisfies constraints solved by the surface simulator. In one embodiment, a method does not utilize a surface simulator.

### CROSS-REFERENCE TO RELATED APPLICATIONS

Not applicable.

### STATEMENT REGARDING FEDERALLY SPONSORED RESEARCH OR DEVELOPMENT

Not applicable.

### TECHNICAL FIELD

The disclosed embodiments relate generally to techniques for generating a reservoir performance forecast.

### BACKGROUND

The hydrocarbon industry recovers hydrocarbons (e.g., oil) that are trapped in subsurface reservoirs (also known as subsurface formations). The hydrocarbons can be recovered by drilling well (also known as wellbores) into the reservoirs and the hydrocarbons are able to flow from the reservoirs into the well and up to the surface. Operation and management of hydrocarbon reservoirs typically rely on reservoir performance forecasts to indicate performance of the reservoir to enable better development planning, drilling strategy, economic outlook, business decisions such as trading and pricing strategies, etc.

### SUMMARY

In accordance with some embodiments, a method of generating a reservoir performance forecast is disclosed. The method includes obtaining inflow performance relationship data generated from a physics-based subsurface-surface coupled simulation model having a surface, a subsurface, and one or more wells fluidly connecting the subsurface to the surface. The inflow performance relationship data comprises performance data for at least one phase of fluid for each well. The method also includes generating a performance forecast for the reservoir using a subsurface simulator and a surface simulator. The subsurface simulator uses the inflow performance relationship data to represent the subsurface during generation of the performance forecast, and the performance forecast satisfies constraints solved by the surface simulator.

In accordance with some embodiments, a method of generating a reservoir performance forecast is disclosed. The method includes obtaining inflow performance relationship data generated from a physics-based subsurface simulation model having a subsurface and one or more wells fluidly connecting to the subsurface. The inflow performance relationship data comprises performance data for at least one phase of fluid for each well. The method also includes generating a performance forecast for the reservoir using a subsurface simulator. The subsurface simulator uses the inflow performance relationship data to represent the subsurface during generation of the performance forecast.

In another aspect of the present invention, to address the aforementioned problems, some embodiments provide a non-transitory computer readable storage medium storing one or more programs. The one or more programs comprise instructions, which when executed by a computer system with one or more processors and memory, cause the computer system to perform any of the methods provided herein.

In yet another aspect of the present invention, to address the aforementioned problems, some embodiments provide a computer system. The computer system includes one or more processors, memory, and one or more programs. The one or more programs are stored in memory and configured to be executed by the one or more processors. The one or more programs include an operating system and instructions that when executed by the one or more processors cause the computer system to perform any of the methods provided herein.

### BRIEF DESCRIPTION OF THE DRAWINGS

FIG. 1 illustrates example elements in a physics-based proxy.

FIG. 2 illustrates IPR curves honoring injection well constraints: producer (left) and injector (right).

FIG. 3 illustrates guide rate balance action.

FIG. 4 illustrates a periodic coupling workflow for production by a CM Proxy engine/subsurface simulator.

FIG. 5 illustrates fully coupled Reservoir A and Reservoir B.

FIG. 6 illustrates predictions: sector model (left) and field-level, performance comparison (right).

FIG. 7 illustrates an oil production rate comparison of randomly selected wells for a sector model.

FIG. 8 illustrates a performance comparison between CM Proxy and fully coupled model in a Q-Q plot (predicting training case, field level).

FIG. 9 illustrates a performance comparison of group MS26 between CM Proxy and fully coupled model (predicting training case).

FIG. 10 illustrates an OAPR comparison of randomly selected wells between CM Proxy and fully coupled model (predicting training case).

FIG. 11 illustrates a workflow of intelligent IPR lookup for multiple training simulations.

FIG. 12 illustrates a prediction of a perturbed case with single training simulation: sector model (left) and well performance (right).

FIG. 13 illustrates an ensemble of oil, water, and gas IPR curves at different cumulative and IPR regeneration with CM Proxy.

FIG. 14 illustrates a prediction of a perturbed case with multiple training models.

FIG. 15 illustrates performance curves of group MS26 from four different training cases and blind test case (fully coupled).

FIG. 16 illustrates a performance comparison of group MS26 between CM Proxy and fully coupled model (predicting perturbed case).

FIG. 17 illustrates a performance comparison between CM Proxy and fully coupled model in a Q-Q plot (predicting perturbed case, field level).

FIG. 18 illustrates how discounted cumulative oil production evolves with generation.

FIG. 19 illustrates an example system for generating a reservoir performance forecast.

FIG. 20 illustrates an example process for generating a reservoir performance forecast.

FIG. 21 illustrates an example of productivity index multiplier of 1.0 in recorded inflow performance relationship data and how the inflow performance relationship responds while a productivity index multiplier of 1.2 or 0.8 is applied while predicting performance.

FIG. 22 illustrates a wide range and non-uniformly sampled pressure points.

FIG. 23 illustrates good resolution of pressure points for practical operation.

FIG. 24 illustrates another example process for generating a reservoir performance forecast.

Like reference numerals refer to corresponding parts throughout the drawings.

### DETAILED DESCRIPTION OF EMBODIMENTS

The surface network model for an oil and gas field usually contains a very detailed analysis of the dynamic conditions in the production facilities and is intended for short-term to mid-term forecasting where the dynamic response to field operating conditions is of interest. The standalone subsurface reservoir model, on the other hand, enables detailed modeling of subsurface reservoir dynamics with fixed assumptions for wellhead pressure and is suitable for forecasting long-term reservoir recovery and for the assessment of reservoir management strategies. Integrated asset modeling, where the subsurface simulation model is coupled with the surface network, is essential to model the interaction between the dynamics in the reservoir and the operating conditions of surface facilities. Integrated asset modeling has been used to generate reliable reserve estimation, perform short- to long-term forecasts, and develop optimum reservoir management strategies. It is especially important for high-stake offshore plays and multiple reservoirs with very complicated surface networks as integrated asset modeling includes the necessary physics to adequately model operational constraints and perform allocations.

The subsurface and surface integrated system could be simulated either loosely coupled or fully coupled. In the loosely coupled approach, the subsurface and surface are modeled with subsurface simulator and surface simulator separately, and the boundary values between them need to be converged at coupled timestep (e.g., Guyaguler, B. and Ghorayeb, K. 2006. Integrated Optimization of Field Development, Planning, and Operation. Paper presented at the SPE Annual Technical Conference and Exhibition, San Antonio, Texas, USA, 24-27 September. SPE-102557-MS, which is incorporated by reference), while in the fully coupled approach, the subsurface reservoir and surface network are essentially within one single simulator, and the combined equations are solved simultaneously. Unsurprisingly, the subsurface and surface coupled simulation brings extra computational challenges in addition to that associated with traditional full-physics simulation. There is a need for the development of proxy for rapid decision-making for reservoir management, and production optimization because of the considerable computational cost.

One common approach to facilitate the simulation of production optimization is to construct the proxy for reservoir response or objective function, which approximates the input/output relations with a set of training simulations. Many types of proxies have been introduced for this purpose. A good review and comparison study of these methodologies was provided by Yeten, B., Castellini, A., Guyaguler, B. et al. 2005. A Comparison Study on Experimental Design and Response Surface Methodologies. Paper presented at the SPE Reservoir Simulation Symposium, The Woodlands, Texas, USA, 31 January-2 February. SPE-93347-MS, which is incorporated by reference. With the increasing research interests of machine learning and artificial intelligence, the machine learning/artificial intelligence-based proxies have also been widely applied recently in oil and gas industry. There are several challenges associated with this approach. For instance, a large number of actual simulations are required to build a reliable proxy, it is difficult to analyze detailed performance as proxies are generally not constructed for fine scale information, and/or the proxies are objective function specific.

On the other hand, researchers also developed numerous techniques to accelerate or approximate the forward subsurface simulation. These techniques include upscaling, reduced-order modeling, flow network modeling (e.g., Wang, Z., He, J., Milliken, W. J. et al. 2021. Fast History Matching and Optimization Using a Novel Physics-Based Data-Driven Model: An Application to a Diatomite Reservoir. Paper presented at the SPE Western Regional Meeting, Virtual, 20-22 April. SPE-200772-MS and Wang, Z., He, J., Milliken, W. J., and X.-H. Wen. “Fast History Matching and Optimization Using a Novel Physics-Based Data-Driven Model: An Application to a Diatomite Reservoir.” SPE J. 26 (2021): 4089-4108. SPE-200772-PA, each of which is incorporated by reference), multiscale finite volume method, streamline-based simulation, and fast marching method-based simulation. Most of these techniques use detailed reservoir simulation models to honor the governing fluid flow physics that come with their corresponding computational cost. One reference presented a concept of integrating constrained optimization with decline curve analysis for well performance prediction. In another reference, production engineers might even replace the subsurface simulator with just tank material balance models. The decline curve analysis-based proxy or material balance models might not be able to accurately capture some physics such as well interference or transient process.

Described below are methods, systems, and computer readable storage media that provide a manner of generating a reservoir performance forecast. One embodiment includes obtaining inflow performance relationship data generated from a physics-based subsurface-surface coupled simulation model having a surface, a subsurface, and one or more wells fluidly connecting the subsurface to the surface. The inflow performance relationship data comprises performance data for at least one phase of fluid for each well. The embodiment also includes generating a performance forecast for the reservoir using a subsurface simulator and a surface simulator. The subsurface simulator uses the inflow performance relationship data to represent the subsurface during generation of the performance forecast. The performance forecast satisfies constraints solved by the surface simulator.

Advantageously, embodiments consistent with the instant disclosure may lead to computational speedup. Computational speedup could be an order of magnitude or more, largely depending on how much portion the surface network simulation takes in fully coupled model simulation. The computation speedup occur even if the surface network is kept intact. The computational time could be further aggressively reduced if the surface network model is also approximated. In one example provided herein, the computational time was reduced from more than 24 hours to about 1.5 hours with more than 95% accuracy preserved.

Indeed, this disclosure provides a non-limiting physics-based subsurface and surface coupled model proxy (CM Proxy), which relies on the trained well inflow performance relationship (IPR) curves. At the training stage, one or multiple full-physics subsurface and surface coupled simulations are performed, from which inflow performance relationship data (e.g., a multiphase IPR database) is constructed for each well. The IPR database captures well performance that represents subsurface reservoir dynamics. At the prediction stage, the computationally intensive reservoir simulation is replaced with IPR curves intelligently looked up from the trained IPR database. Based on the models tested, the proxy could achieve more than 95% accuracy. The surface network model was retained to investigate the impact of different surface operations, such as maintenance schedule and production routing changes. As the computationally intensive part is replaced with IPR curves, this approach could significantly reduce the run time of the coupled simulation. The overall speedup generally could be an order of magnitude, depending on the complexity of the surface network model. This makes the approach suitable for the rapid evaluation and optimization of the surface network operation.

The instant disclosure explains the non-limiting methodology of the CM Proxy followed by the non-limiting example application. The instant disclosure also explains a non-limiting methodology for handling multiple training simulations to enhance the applicability of the proxy model. The non-limiting CM Proxy is also applied to an optimization problem, which demonstrates the powerful capability to enable rapid decision-making for reservoir management.

Reference will now be made in detail to various embodiments, examples of which are illustrated in the accompanying drawings. In the following detailed description, numerous specific details are set forth in order to provide a thorough understanding of the present disclosure and the embodiments described herein. However, embodiments described herein may be practiced without these specific details. In other instances, well-known methods, procedures, components, and mechanical apparatus have not been described in detail so as not to unnecessarily obscure aspects of the embodiments.

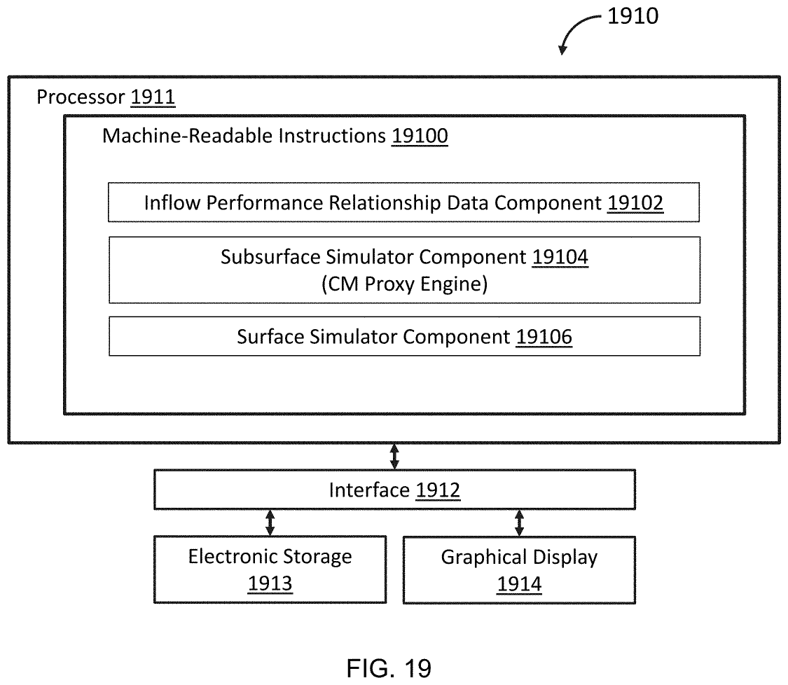

The methods and systems of the present disclosure may be implemented by a system and/or in a system, such as a system 1910 shown in FIG. 19. The system 1910 may include one or more of a processor 1911, an interface 1912 (e.g., bus, wireless interface), an electronic storage 1913, a graphical display 1912, and/or other components. The processor 1911 will execute a method of generating a reservoir performance forecast. The processor obtains inflow performance relationship data generated from a physics-based subsurface-surface coupled simulation model having a surface, a subsurface, and one or more wells fluidly connecting the subsurface to the surface. The inflow performance relationship data comprises performance data for at least one phase of fluid for each well. The processor also generates a performance forecast for the reservoir using a subsurface simulator and a surface simulator. The subsurface simulator uses the inflow performance relationship data to represent the subsurface during generation of the performance forecast. The performance forecast satisfies constraints solved by the surface simulator.

The electronic storage 1913 may be configured to include electronic storage medium that electronically stores information. The electronic storage 1913 may store software algorithms, information determined by the processor 1911, information received remotely, and/or other information that enables the system 1910 to function properly. For example, the electronic storage 1913 may store information relating to the inflow performance relationship data, the production forecast, constraint(s), and/or other information. The electronic storage media of the electronic storage 1913 may be provided integrally (i.e., substantially non-removable) with one or more components of the system 1910 and/or as removable storage that is connectable to one or more components of the system 1910 via, for example, a port (e.g., a USB port, a Firewire port, etc.) or a drive (e.g., a disk drive, etc.). The electronic storage 1913 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 1913 may be a separate component within the system 1910, or the electronic storage 1913 may be provided integrally with one or more other components of the system 1910 (e.g., the processor 1911). Although the electronic storage 1913 is shown in FIG. 19 as a single entity, this is for illustrative purposes only. In some implementations, the electronic storage 1913 may comprise a plurality of storage units. These storage units may be physically located within the same device, or the electronic storage 1913 may represent storage functionality of a plurality of devices operating in coordination.

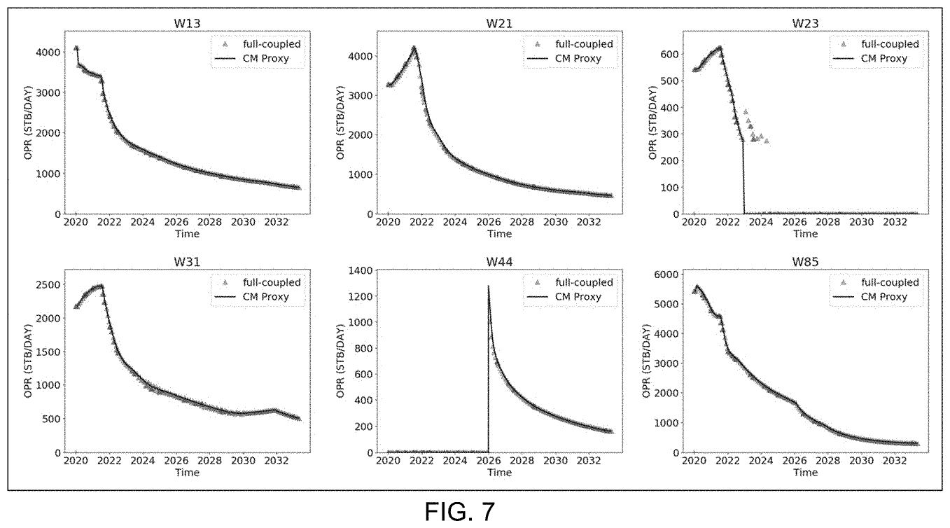

The graphical display 1914 may refer to an electronic device that provides visual presentation of information. The graphical display 1914 may include a color display and/or a non-color display. The graphical display 1914 may be configured to visually present information. The graphical display 1914 may present information using/within one or more graphical user interfaces. For example, the graphical display 1914 may present information relating to the inflow performance relationship data, the production forecast, the constraint(s), and/or other information. For example, the inflow performance relationship data may be visually presented in the form of tables, spreadsheets, etc. For example, the production forecast may be visually presented in form of curves, diagrams, etc. such as illustrated in FIG. 7.

The processor 1911 may be configured to provide information processing capabilities in the system 1910. As such, the processor 1911 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 1911 may be configured to execute one or more machine-readable instructions 19100 to generate a reservoir performance forecast. The machine-readable instructions 19100 may include one or more computer program components. The machine-readable instructions 19100 may include an inflow performance relationship data component 19102, a subsurface simulator component 19104 (also referred to as a CM proxy engine or simply subsurface simulator), a surface component 19106 (also referred to as surface network simulator or simply surface simulator), and/or other computer program components.

It should be appreciated that although computer program components are illustrated in FIG. 19 as being co-located within a single processing unit, one or more of computer program components may be located remotely from the other computer program components. While computer program components are described as performing or being configured to perform operations, computer program components may comprise instructions which may program processor 1911 and/or system 1910 to perform the operation.

While computer program components are described herein as being implemented via processor 1911 through machine-readable instructions 19100, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

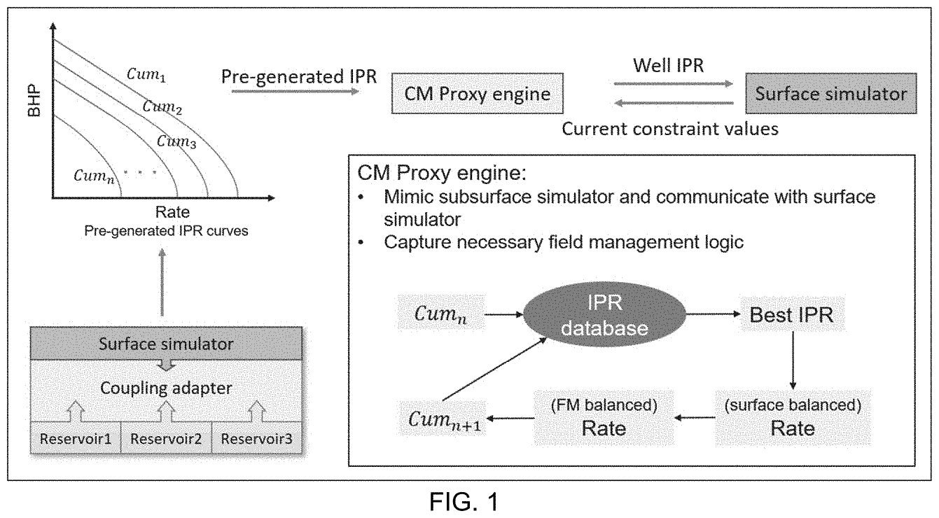

Referring again to machine-readable instructions 19100, the inflow performance relationship data component 19102 may be configured to obtain inflow performance relationship data generated from a physics-based subsurface-surface coupled simulation model having a surface, a subsurface, and one or more wells fluidly connecting the subsurface to the surface. The inflow performance relationship data comprises performance data for at least one phase of fluid for each well. The term “obtaining” may include receiving, retrieving, accessing, generating, etc. or any other manner of obtaining data. At the training stage, the inflow performance relationship data component 19102 may receive, retrieve, and/or access the inflow performance relationship data that was previously generated using at least one reservoir model run by the subsurface simulator component 19104, a coupling adapter, and at least one surface model run by the surface simulator component 19106 (e.g., FIG. 1). At the training stage, the inflow performance relationship data component 19102 may generate the inflow performance relationship data using at least one reservoir model run by the subsurface simulator component 19104, a coupling adapter, and at least one surface model run by the surface simulator component 19106 (e.g., FIG. 1).

The “coupling adapter” is a script which is responsible for data transferring and data communication between the subsurface simulator component 19104 and the surface simulator component 19106. The coupling adapter may be implemented together with the main simulator (such as subsurface simulator) in the coupled simulation workflow. A person of ordinary skill in the art will appreciate that there may be other ways to generate the inflow performance relationship data than those described herein.

The subsurface simulator component 19104 (also referred to as the CM proxy engine herein) component 19104 may be configured to be used in the training stage as discussed hereinabove and in the prediction stage. Similarly, the surface simulator component 19106 may be configured to be used in the training stage as discussed hereinabove and in the prediction stage. The processor 1911 generates a performance forecast for the reservoir using the subsurface simulator component 19104 and the surface simulator component 19106. The subsurface simulator component 19104 uses the inflow performance relationship data to represent the subsurface during generation of the performance forecast, and the performance forecast satisfies constraints solved by the surface simulator component 19106.

The subsurface simulator component 19104 is also configured, in the prediction stage, to determine which inflow performance relationship to utilize for each well at each prediction time-step based on the inflow performance relationship data. Linear interpolation based on cumulative production, cumulative injection, or any combination thereof may be utilized at each prediction time-step to determine which inflow performance relationship to utilize for each well. Kriging or a neural network based on cumulative production, cumulative injection, or any combination thereof from each well and its neighboring wells is utilized at each prediction time-step to determine which inflow performance relationship to utilize for each well. The neighboring wells are determined based on user specified criteria. The subsurface simulator component 19104 is also configured, at the prediction stage, to implement field management (FM) logic, such as guide rate balance and conditional well shut-in.

The subsurface simulator component 19104 is also configured, in the prediction stage, to perform truncation. The determined inflow performance relationships are truncated in response to flow constraints for each well. The flow constraints may comprise bottom hole pressure, tubing head pressure, injection rate, production rate, or any combination thereof.

The subsurface simulator component 19104 is also configured, in the prediction stage, to computing a range of pressure points within the inflow performance relationship data for each well to generate the performance forecast for the reservoir.

The surface simulator component 19106 is also configured, in the prediction stage, solve pressure and rate constraints of equipment on the surface during generation of the performance forecast. The surface simulator component 19106 uses a surface network model to represent the surface during generation of the performance forecast. Alternatively, the surface simulator component 19106 uses a proxy to represent the surface during generation of the performance forecast. The proxy used by the surface simulator component 19106 comprises a table lookup or a neural network

The description of the functionality provided by the different computer program components described herein is for illustrative purposes, and is not intended to be limiting, as any of computer program components may provide more or less functionality than is described. For example, one or more of computer program components may be eliminated (e.g., the surface simulator component 19106 may be eliminated in some embodiments), and some or all of its functionality may be provided by other computer program components. As another example, processor 1911 may be configured to execute one or more additional computer program components that may perform some or all of the functionality attributed to one or more of computer program components described herein.

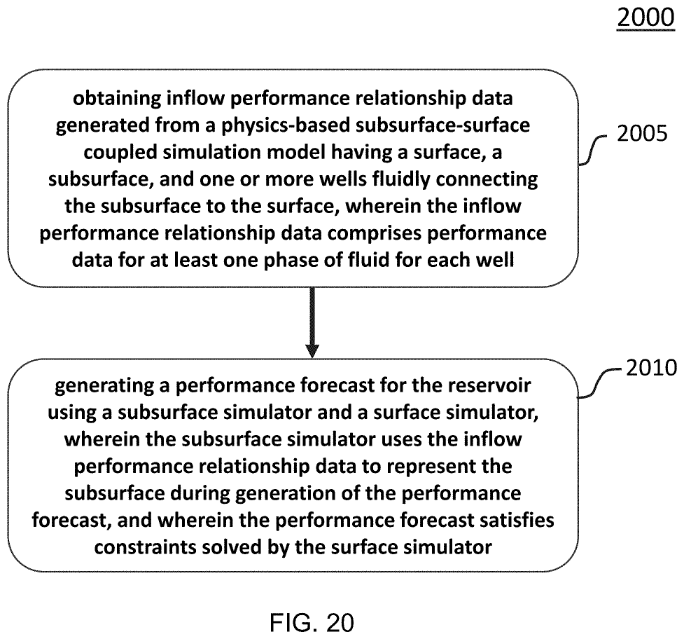

FIG. 20 illustrates an example process 2000 for generating a reservoir performance forecast. In process 2000, a physics-based subsurface and surface CM Proxy includes two stages (i.e., training and prediction). FIG. 1 illustrates elements of this non-limiting workflow. This workflow is not simulator specific (i.e., both subsurface simulator and surface simulator could be of practitioner's own choice).

At step 2005, the process 2000 includes obtaining inflow performance relationship data generated from a physics-based subsurface-surface coupled simulation model having a surface, a subsurface, and one or more wells fluidly connecting the subsurface to the surface. The inflow performance relationship data comprises performance data (e.g., cumulative oil production, cumulative gas production, cumulative water production, cumulative water injection, cumulative gas injection, or any combination thereof) for at least one phase of fluid for each well. The at least one phase comprises a gas phase, an oil phase, a water phase, or any combination thereof. The term “obtaining” may include receiving, retrieving, accessing, generating, etc. or any other manner of obtaining data. The inflow performance relationship data for each well may be generated as a function of cumulative production, as a function of cumulative injection, as a function of bottom hole pressure, as a function of tubing head pressure, or any combination thereof. The inflow performance relationship data for each well may be generated using productivity index multiplier data in response to an acid treatment, a fracturing operation (e.g., hydraulic fracturing operation, fracturing using electrodes, etc.), formation damage (e.g., skin factor) (see also US Patent Publication No. 2021/0096277 and Zaki, et al., “Productivity Decline: The Underlying Geomechanics and Contributing Damage Factors”, SPE Annual Technical Conference and Exhibition, Calgary, Alberta, Canada, 30 Sep.-2 Oct. 2019: SPE-196223-MS, each of which is incorporated by reference), rock geomechanics (e.g., permeability change as a function of pressure, porosity change as a function of pressure), or any combination thereof. The inflow performance relationship data may be generated from a single physics-based subsurface-surface coupled simulation model. The inflow performance relationship data may be generated from multiple physics-based subsurface-surface coupled simulation models.

Regarding the productivity index multiplier data, a productivity index is defined by the production rate divided by the pressure difference between reservoir and well bottom-hole pressure. In numerical simulation, a multiplier (productivity index multiplier) is introduced to manually adjust the productivity index to model certain events, such as acid treatment, a fracturing operation, formation damage, and rock geomechanics effect. Productivity index multiplier is default at 1.0 and is a single value at each simulation time for each well.

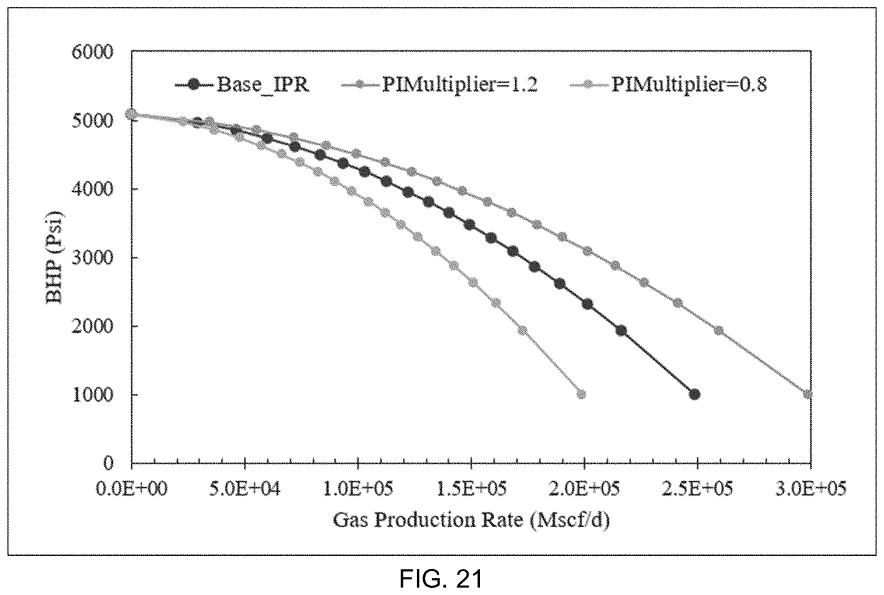

Like cumulative production and injection, the process 2000 may include recording the productivity index multiplier value corresponding to each inflow performance relationship data generated from a physics-based subsurface-surface coupled simulation. When predicting the performance, the production index multiplier from the prediction case is compared with the value from recorded value corresponding to inflow performance relationship data at each time step, the generated inflow performance relationship is shifted by the ratio of production index multiplier from the prediction case to recorded value corresponding to inflow performance relationship data. FIG. 21 illustrates an example of productivity index multiplier of 1.0 in recorded inflow performance relationship data and how the inflow performance relationship responds while a productivity index multiplier of 1.2 or 0.8 is applied while predicting performance. More information about the productivity index multiplier may be found at Zhang, Yanfen, “Integrated PI Degradation Modeling IPDM.” Paper presented at the SPE Annual Technical Conference and Exhibition, Virtual, Oct. 21, 2020, SPE-201650-MS, which is incorporated by reference.

Returning to step 2005, as an example, at the training stage, full-physics subsurface and surface coupled simulations are performed to generate multiphase (oil, gas, and water) IPR curves (inflow performance relationship data). For each well, the IPR curve of each phase is recorded as a function of cumulative production, which implicitly represents the time information. More specifically, as shown in Equation 1, each phase rate is treated as a function of bottom hole pressure (BHP) and phase cumulative production. The phase cumulative productions are correlated in a single training simulation case but could be treated as independent variables in multiple training simulations scenario, which will be covered in the later section. Here, each IPR curve is estimated and recorded in a table format, which has no restriction on whether the curve is linear or nonlinear. In addition to IPR curves, the definition and modification of wells and groups are extracted and recorded from the training simulations, which will serve as part of prediction inputs. This information includes well name, type, status, constraints, and group members and their constraints:

qₚ=f(bhp,cumₒ,cum_{g},cum_{w}),p=o,g,w Equation 1:

Explicit subsurface-surface coupling is adopted for its flexibility and the rates at the subsurface-surface boundary are expressed at standard conditions. With these setups, the subsurface simulation part could handle multiple reservoirs even with different equations of state, while the surface models use a black-oil fluid description. The coupling is performed periodically at well sandface, which means bottom-hole pressure (BHP) is the boundary condition. One advantage of choosing BHP instead of tubing-head pressure (THP) as boundary condition is that the vertical lift performance may be accurately handled by the surface simulator while applying the CM Proxy. It should be noted that the subsurface reservoir model should be a calibrated model, which can honor historical data, to provide reliable reservoir performance prediction for the field development plan.

At step 2010, the process 2000 includes generating a performance forecast for the reservoir using a subsurface simulator and a surface simulator. The subsurface simulator uses the inflow performance relationship data to represent the subsurface during generation of the performance forecast, and the performance forecast satisfies constraints solved by the surface simulator. In some embodiments, generating the performance forecast comprises determining which inflow performance relationship to utilize for each well at each prediction time-step based on the inflow performance relationship data. Linear interpolation based on cumulative production, cumulative injection, or any combination thereof may be utilized at each prediction time-step to determine which inflow performance relationship to utilize for each well. Kriging or a neural network based on cumulative production, cumulative injection, or any combination thereof from each well and its neighboring wells is utilized at each prediction time-step to determine which inflow performance relationship to utilize for each well. The neighboring wells are determined based on user specified criteria (e.g., distance, interwell connectivity). Some embodiments may perform truncation such that the determined inflow performance relationships are truncated in response to flow constraints for each well. The flow constraints may comprise bottom hole pressure, tubing head pressure, injection rate, production rate, or any combination thereof. Some embodiments include computing a range of pressure points within the inflow performance relationship data for each well to generate the performance forecast for the reservoir. FIG. 7 illustrates some non-limiting examples of performance forecasts.

Regarding computing a range of pressure points, the accuracy of the inflow performance relationship data generated from a physics-based subsurface-surface coupled simulation is an important step to ensure the accuracy of the following performance prediction. The inflow performance relationship data is sampled at discretized pressure points. It is important and challenging to design these sampling pressure data points to extract as much and accurate information as possible. Thus, the process 2000 may include a uniform process to handle it that accounts for different productivity, operation limits, and field management logic for each well.

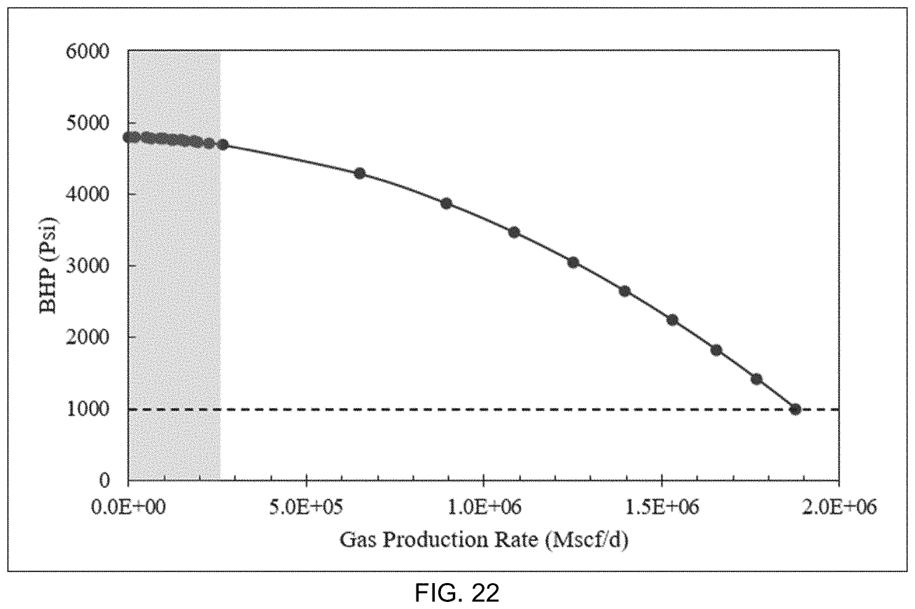

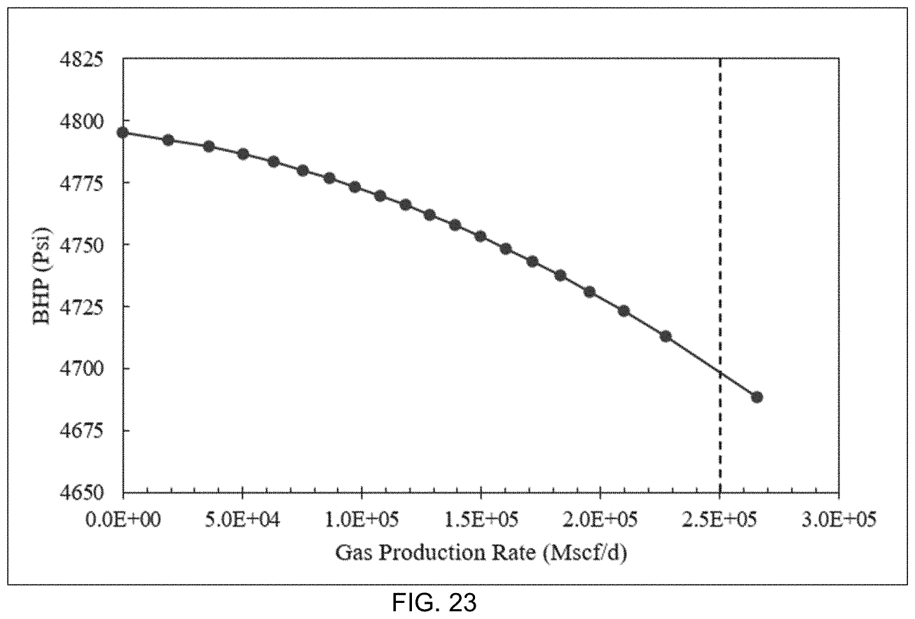

Take a producer as an example: 1) the max pressure data point based on no-flow pressure (i.e., the max pressure well could barely produce oil) and the minimum pressure data point is based on specified pressure constraints on well (e.g., atmosphere pressure 14.7 psi is used if no pressure constraint is specified). The production rate corresponding to the minimum pressure data point is called potential rate. It is important to be recorded in this non-limiting example as it serves the basis for rate allocation among different wells based on user specification in field management logics. 2) allow skewness to sample nonuniformly between the max and min pressure data points. 3) When well has high productivity, the generated well inflow performance relationship data will cover a large range of production rate, but there will be sparse data point within the operation limits (e.g., max production rate constraint). An iteration procedure is implemented to estimate the pressure close to the operation limit. 4) pressure data points are refined within the operation limit range to avoid inaccuracy caused by data sparsity. 5) pressure data points are consolidated to account for the entire range as well as the accuracy within operation limit. More information regarding computing the range of pressure points is illustrated in in FIGS. 22-23.

Returning to step 2010, as an example, at the prediction stage, the CM Proxy engine, acting as the subsurface simulator, will determine/regenerate the most appropriate IPR for each well based on the pretrained IPR database and communicate with the surface network simulator. The CM Proxy engine implements the FM logic, such as guide rate balance and conditional well shut-in. The CM Proxy engine may have its own time controller that could proceed itself and determine when to couple with the surface network. At each coupled timestep, the CM Proxy engine will compute the “best” IPR (e.g., the IPR which represents the well current production or injection potential as accurate as possible) for each well based on the cumulative production information at that time. The well IPR curves are then passed to the surface network to obtain solved rate allocation honoring surface network constraints, such as separator pressure and pipeline network pressure balance. The surface network solution comes from the intersection between the IPR curve and the corresponding vertical lift performance curve, will honor the separator pressure, and balance the pressure of the entire pipeline network. The FM logic of the CM Proxy engine will further balance the allocation and compute the final production rate for this timestep. In this example, the CM Proxy engine is loosely coupled with the surface network (i.e., FM balanced well boundary solutions will not iterate with the surface network again). On the one hand, the CM Proxy is designed to generate approximated solutions. On the other hand, multiple iterations require multiple surface network computations, which will counteract the benefit of proxy simulation, especially when solving the surface network is expensive.

Continuing with this example, for each prediction run, the CM Proxy engine inherits the well/group definition and corresponding IPR database from the trained base model. The prediction scenario can be different from the training models in several aspects, such as well schedule changes, group member reassignment, well/group constraints modifications, and surface network operation changes. In addition, the FM logic, such as the target rate for guide rate balance action and the conditions for well shut-ins, is also allowed to change in the prediction runs.

It is important to accurately determine/regenerate representative IPR curve for each well at each coupled timestep. Linear interpolation is utilized for scenarios having only a single training simulation and an advanced IPR lookup strategy (e.g., Kriging or a neural network) is used for cases with multiple training runs, which will be presented in the multiple training simulations section hereinbelow. Because the oil, gas, and water production is implicitly correlated in the single training simulation case, the oil phase is handled as the independent variable. As shown by Equation 2, the IPR curve for cumₒ is constructed as a linear combination of IPRs at cum_{o,i} and cum_{o,i+1}, where w₁ and w₂ are the linear interpolation weights:

IPRₚ=f(cumₒ)=w₁*IPRₚ(cum_{o,i})+w₂*IPRₚ(cum_{o,i+1}),cum_{o,i}≤cumₒ<cum_{o,i+1} Equation 2:

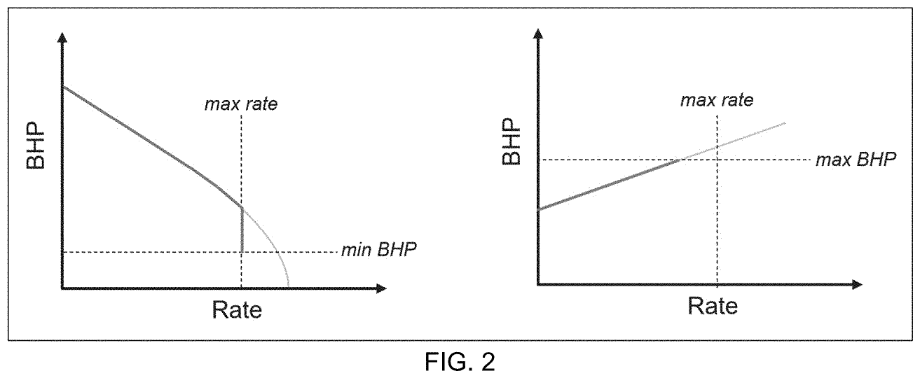

Continuing with this example, the CM Proxy will impose any well constraints input by users on the generated IPR curves before sending IPR curves to the surface network. Typical well constraints include maximum production rate and minimum producing pressure for producers, and maximum injection rate and maximum injecting pressure for injectors. The IPR curves are truncated according to the limiting well constraint. For the specific example illustrated by FIG. 2, the limiting constraints are maximum production rate for producers and maximum injecting BHP for injectors. This process will avoid the unrealistic solution from surface network evaluation (i.e., a violation of any of the constraints).

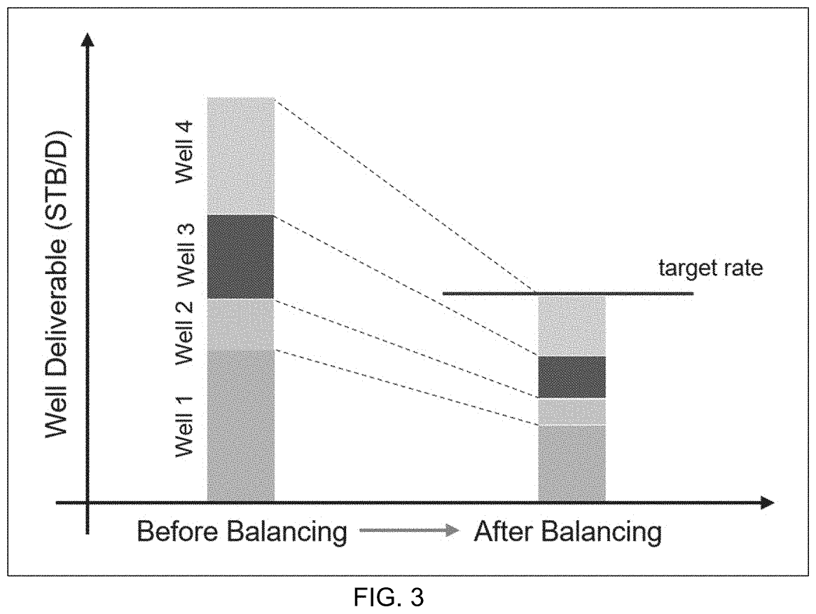

Continuing with this example, the same FM logic that is in the fully coupled model needs to be replicated in the CM proxy to make their result comparable. The set of FM logic, such as rate allocation and conditional well shut-ins/workovers, reflects human decision rather than reservoir physics. The typical allocation rule used in reservoir simulation is based on guide rates, which is used to apportion targets among members of each group while honoring the constraints and shutting the uneconomic wells. The guide rates could be either potential rates (the flowing rate with all constraints removed except those pressure constraints directly set by user input) or deliverable rates (the flowing rate with all constraints removed except those pressure and rate constraints directly set by user input). Continuing with this example, the deliverable rates are selected because both rate and pressure constraints will be available after surface network evaluation. FIG. 3 illustrates a simple guide rate balance action, where well rates are rescaled proportionally to their deliverable rates to honor group rate constraint.

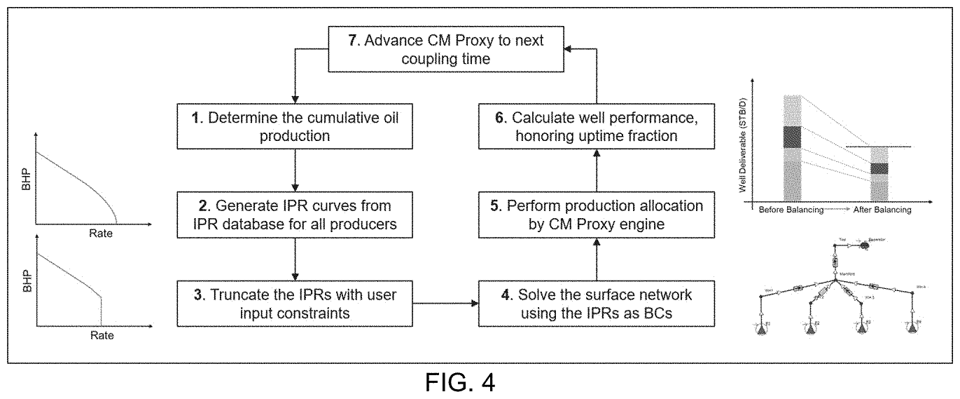

FIG. 4 provides a detailed summary of all the items discussed above for one coupling timestep in CM Proxy engine. It is illustrated with the production system, and the workflow for injection is conceptually similar.
1. Each coupling timestep starts with the determination of the cumulative oil production. For the first timestep, it will be 0 for nonrestart simulation or the recorded historical value for restart simulation. For the following timestep, it will be calculated from the previous timestep based on the determined rate and timestep size.
2. For each well, the cumulative oil production at the current timestep acts as the independent variable, and an IPR curve is generated using linear interpolation from the IPR database (inflow performance relationship data).
3. The generated IPRs are truncated based on any pressure/rate constraints from the user input.
4. The truncated IPRs are passed to the corresponding wells in the surface network, and then the entire surface network is solved to determine the intersection between the IPR curves and the vertical lift performance curves. The surface network system is solved with a steady-state solution.
5. The surface network solution then serves as the deliverable rate constraints for each well and the CM Proxy engine performs guide rate balance action based on field development strategy.
6. The well performance (e.g., allocation rates and cumulative production) is then calculated. Note that in steps 4 and 5 in FIG. 4, instantaneous capacity is considered, which assumes all wells are at the full flowing conditions and ignores well uptime fraction. The uptime fraction is accounted for at this step.
7. Advance the CM Proxy to the next coupling timestep and repeat the process.

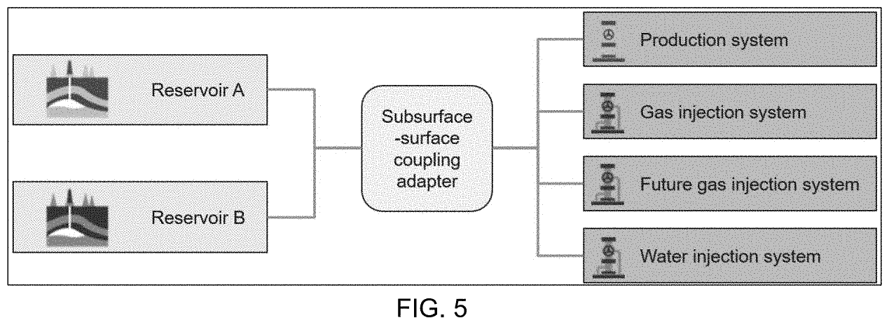

EXAMPLE APPLICATION (predicting the training case): The development of the physics-based CM Proxy is driven by the desire to speed up the fully coupled simulation models of two super giant fields (Reservoir A and Reservoir B, as illustrated by FIG. 5). Both reservoir simulation models use dual porosity and dual permeability (DPDK) discretization. There are approximately 1.3 million active grid cells (matrix and fracture) for Reservoir A and 280,000 active cells for Reservoir B. The combined models contain more than 300 wells. The surface network model contains very detailed and complex production facilities including more than 600 flow lines, over 30 metering stations, and trunk lines and manifolds. There are four facility systems in this surface network model: production facilities, current sour gas injection, future sour gas injection, and water injection system.

One top priority for the field development is to optimize production and operation to meet the increased production capacities (i.e., keep the plant full) in the future. These strategies include the sequence and timing of converting existing metering stations from high-pressure to low-pressure operation and the sequence and timing of drilling new infill wells (e.g., put-on-production schedule from simulation perspective) given rig resource constraints. This optimization process usually requires many evaluations of the coupled reservoir performance, which is extremely time consuming because a single simulation of the coupled two-reservoir models generally takes more than 24 hours on parallel Linux clusters. It calls for the development of proxy to facilitate the simulation process to be able to optimize the production and operation strategies in a timely manner. The physics-based CM Proxy provided herein could bring the computational time of this coupled simulation down to about 1.5 hours on Windows workstations (as the surface network simulator is a Windows application); the remaining time is mainly consumed by the surface network computation.

In this example application, the well schedule/control and FM for the CM Proxy are the same as that for in fully coupled model. This step is to demonstrate the validity of replacing the subsurface reservoir simulator with both the pretrained IPR database and the appropriate implementation of the FM logic.

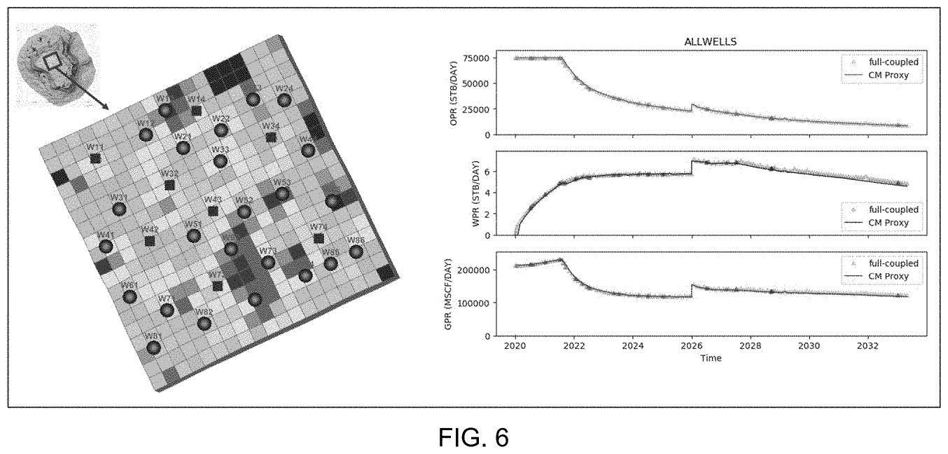

The CM Proxy is first applied to a synthetic model (a sector cut from Reservoir A), shown by FIG. 6 (left). The training case contains 24 producers and 8 injectors, with simple field-level guidance rates (OPR and GIR) imposed. OPR stands for oil production rate. FIG. 6 (right) presents the field-level comparison of OPR, WPR, and GPR between CM Proxy and fully coupled simulation (note that the fully coupled simulation here serves as both training model and test model). It can be observed that the CM Proxy could almost exactly reproduce the fully coupled simulation results. FIG. 7 plots the OPR comparisons for several randomly selected wells. The match is very accurate at well level, except for some data points (well W23) where well has oscillation during the full subsurface and surface coupled solving.

For real field application, the field-level performance comparison is presented in Q-Q plot with normalized scale and the actual values of other results are omitted because of data confidentiality.

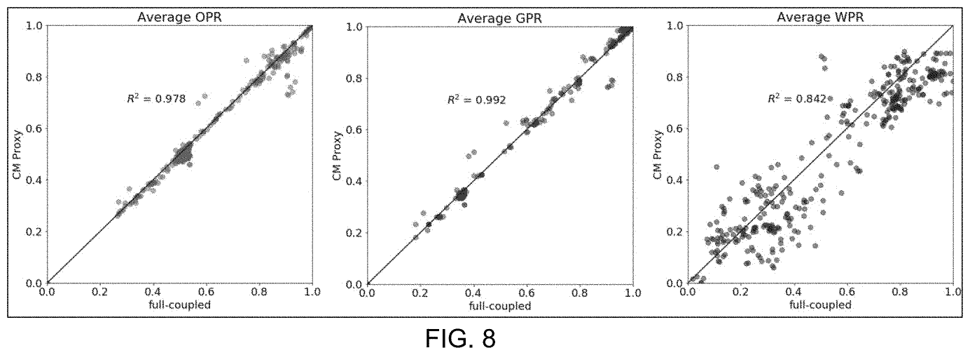

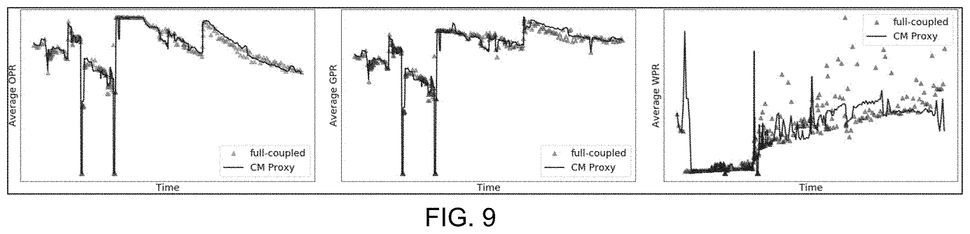

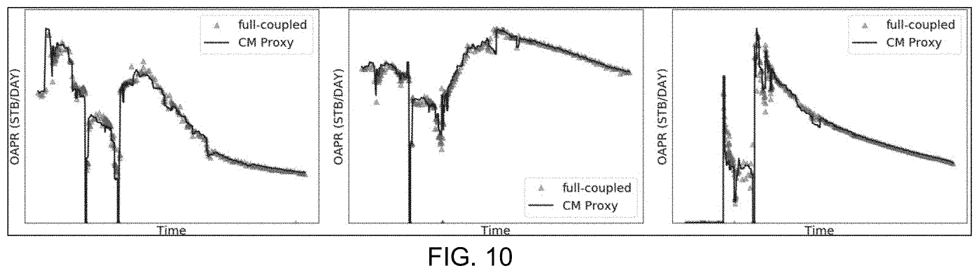

FIG. 8 plots field-level production rates comparison, where 45° line indicates 100% accuracy. The oil and gas rates in FIG. 8 fall on 45° line or very nearby (with R2 above 0.97), indicating very good accuracy of the CM Proxy. The minor discrepancy is because of some nonreplicable FM logic, such as conditional completion workover. FIG. 9 presents the average production rate (considering uptime fraction) comparison for one group of wells (group MS26) from simulations via the CM Proxy and the fully coupled model. The CM Proxy is observed to reproduce the fully coupled model results quite accurately, especially for the oil and gas production rates. The discrepancy for water production rates looks larger because the actual values are two orders of magnitude smaller than oil production rates (e.g., WCT is just about 1%). FIG. 10 further compares the average oil production rates for three randomly selected wells. The good accuracy is observed at well level almost for all the wells.

MULTIPLE TRAINING SIMULATIONS: The above example applications presents the CM Proxy results predicting the training case, while the goal of CM Proxy development is the capability to predict perturbed cases as accurately as possible, where production and operation strategies are different from the training case. The CM Proxy trained on a single simulation case might have a limited applicability scope if a high accuracy is desired. For instance, if a well is put on production later than it was during the training scenario, the performance of that well will most likely be different because of the additional drainage by the neighboring wells. Looking up the IPR curve solely based on the well's own OPC is unlikely to capture the well interference effect. Well interference describes the effect that the target well will have different potentials at the same time or cumulative production because the neighboring wells have produced or injected different amounts. To resolve this issue, the lookup mechanism of the IPR database may be based on not only the features of the wells under investigation but also the features of the adjacent wells. Of course, the need for more features to enrich the IPR database may require more data from multiple training simulations.

The purpose of varying model settings to generate multiple training simulations is to account for well interference. Therefore, any parameters which lead to different well interference from neighboring wells could be of consideration (the instant disclosure considers the put-on-production of different wells or groups of wells). The change of parameters in training cases cover the range of prediction cases (e.g., dealing with interpolation problem instead of extrapolation problem) to estimate the well interference more accurately while regenerating IPR curves.

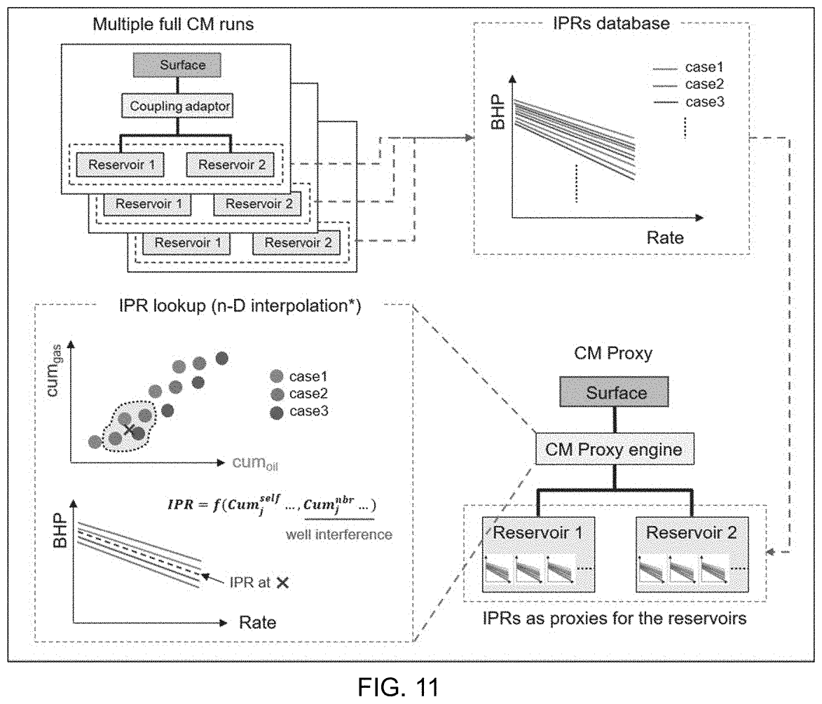

The following workflow, illustrated by FIG. 11, is developed in CM Proxy to handle multiple training simulations. At the training stage, multiple fully coupled model runs are performed and IPR curves are recorded at each coupled timestep per well and run. At the prediction stage, CM Proxy will read the entire IPR database and then perform an intelligent IPR curve lookup. The lookup strategy is not only based on the current cumulative oil production of the well because there are multiple distinctive IPR curves corresponding to one cumulative production. Instead, CM Proxy will consider both the multiphase cumulative production of that well itself as well as the cumulative production/injection of its neighboring wells. Equation 3 defines the generic form for producers, where superscript self indicates the considering well itself and nbr stands for the group of neighboring wells to account for well interference. Depending on the specific problem, some of these terms could be excluded, for instance, wic term could be omitted if there is no water injection in the system at all. Similarly, the IPR lookup for injectors will depend on the cumulative water/gas injection of itself and the cumulative production/injection of its neighboring wells.

A nonpartitioning approach is utilized to construct the neighboring wells for individual well, instead of dividing the reservoir domain into several fixed regions. CM Proxy creates a map, which links individual well with its neighboring wells, defined based on the absolute well distance cutoff specified by the user. One advantage of this approach is that the training simulations are intact, and any future modifications of the neighboring well definition only occur at the prediction stage. It is more realistic as two nearby wells can not only share the same neighboring wells but also have their own distinct neighbors.

The IPR curve lookup is now dealing with multiple dimensional features because of the multiphase cumulative information for both the well itself and its neighboring wells. All neighboring wells are lumped as a group, instead of being treated separately, to reduce the dimensions of features and increase the efficiency of the IPR lookup algorithm. This treatment makes sense as the remaining energy matters more from the material balance perspective. Depending on the number of training simulations, different IPR curve lookup algorithms can be adopted. For instance, if there are hundreds or even thousands of training simulations, advanced and complicated algorithms such as neural network-based machine learning will provide a more accurate IPR determination/regeneration. However, if it is the case with only a few training simulations (when simulating the fully coupled model takes an extremely long time), a simple and efficient algorithm is preferred.

In this non-limiting example of multiple training simulations, the IPR curve for each well is determined/regenerated using Kriging from the trained IPR database based on the status of itself and its neighboring wells. Kriging is adopted here because this algorithm is straightforward and emphasizes more on the closer data points (i.e., more similar status).

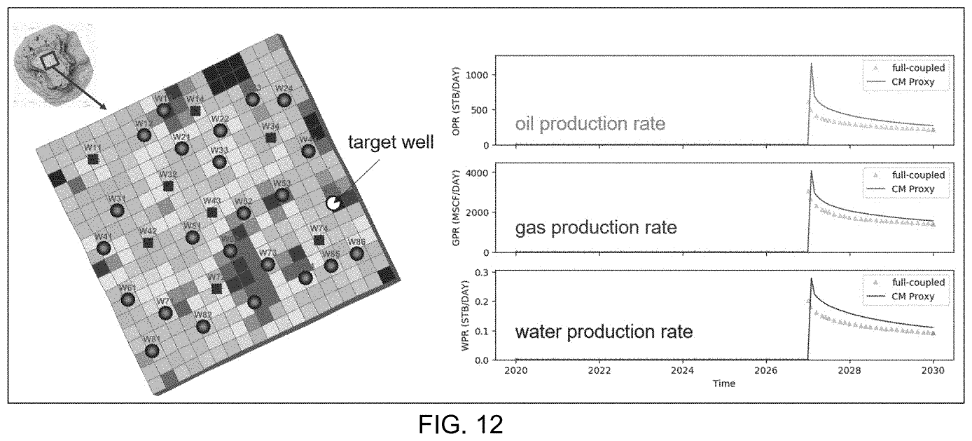

Next, the accuracy improvement using multiple training simulations to predict a synthetic model performance will be demonstrated. The CM Proxy prediction from a single training simulation is first presented (FIG. 12). In the instant disclosure, the put-on-production schedule of the target well (W63) is perturbed (everything else is kept the same). The target well begins to produce in year 2023 in training simulation while it begins to produce in year 2027 in the prediction case. There are quite noticeable differences as shown in FIG. 12, where it can be observed that the CM Proxy is over predicting the performance. Because it is based on target well cumulative production information only, it has no clue of the following well interference in the same period. In addition, two more perturbed scenarios were tested with different put-on-production schedules (in year 2025 and 2029) to investigate the sensitivity of the perturbation. As expected, more accurate predictions were obtained in scenarios that are closer to the single training scenario.

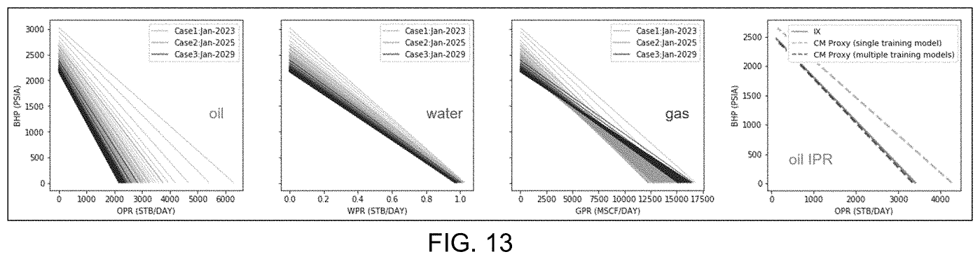

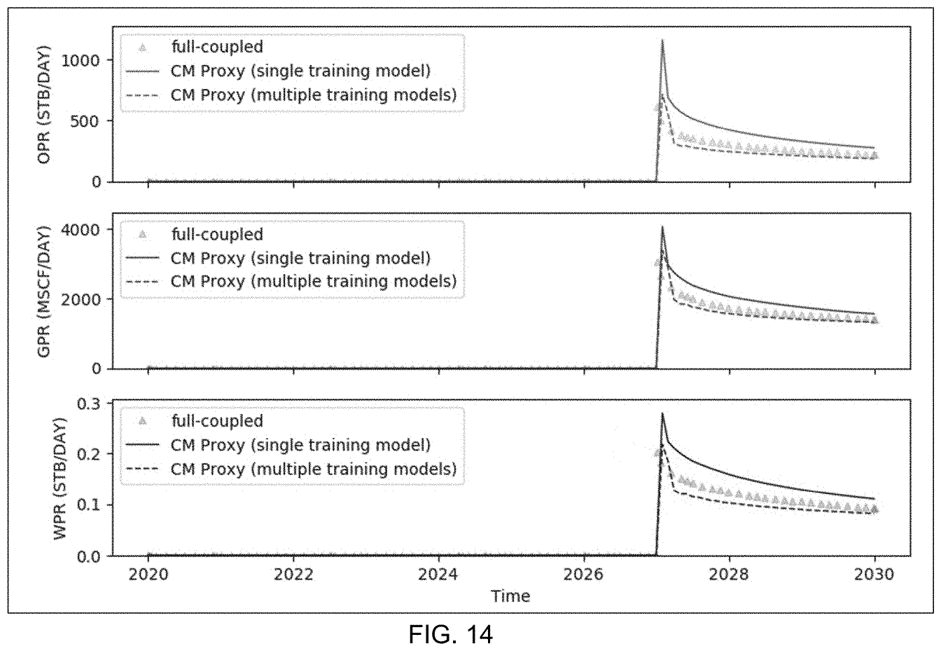

FIG. 13 (left) presents how the IPR curves evolve for each phase at different times for three different scenarios, where the only difference is the put-on-production schedule of the target well (in year 2023, 2025, and 2029 respectively). The obvious differences demonstrate the strong well interference and the use of multiple training simulations to capture that. The workflow discussed above is applied to handle the multiple training simulations. FIG. 13 (right) shows the oil IPR curves from the true simulation, determined/regenerated with single and multiple training simulations in year 2027, when the target well begins to produce in the predicting/test case. FIG. 14 provides the well performance comparison of the target well. These two figures clearly show that the multiple training simulations (even though just three runs in this case) improve the accuracy. It is worth mentioning that, as in any other data-driven approach, extrapolation is generally not encouraged. However, it can possibly occur in some situations (e.g., limited number of training simulations, complex constraints, and FM logic). The CM Proxy would still provide reasonable predictions as shown in FIG. 12. This is because the extrapolated IPRs are not purely data-driven but physics-informed by the nearest IPRs generated from the full-physics simulations.

EXAMPLE APPLICATION (Predicting on Perturbed Case): For the fully coupled model application, four training cases and one blind test case are provided by the Business Unit. The differences among these cases are the start date of three groups of producers and two groups of injectors (each group contains three to five wells). These wells are grouped according to the actual multiwell pads.

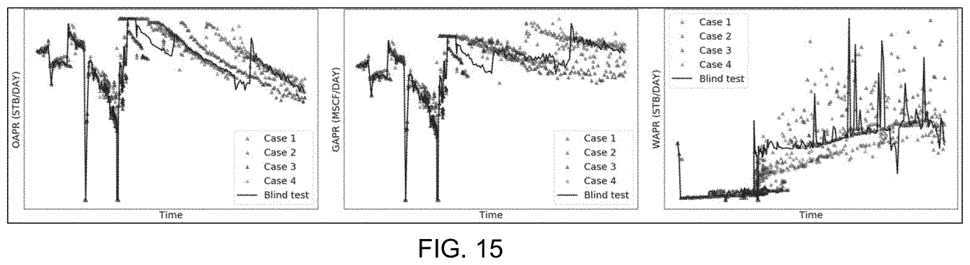

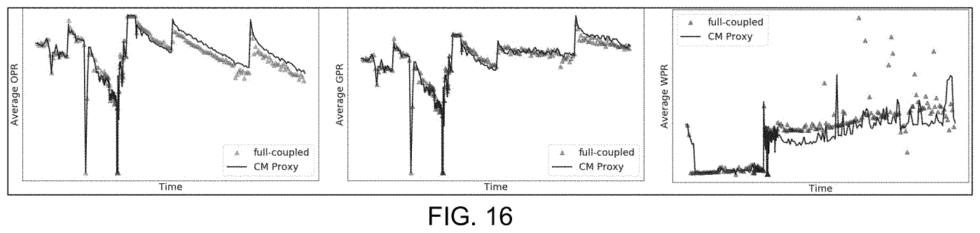

The well interference will lead to different IPR curves across different scenarios, and then different IPR curves are passed through surface network solve and FM logic, which yield different well and group performances. FIG. 15 plots the performance curves of group MS26 from four different training cases and the blind test case. Significant differences caused by well interference can be observed among these cases. FIG. 16 presents the CM Proxy performance comparison with multiple training simulations. It demonstrates that even though the training cases are noticeably different from the test case, the CM Proxy could reproduce the test case with good accuracy.

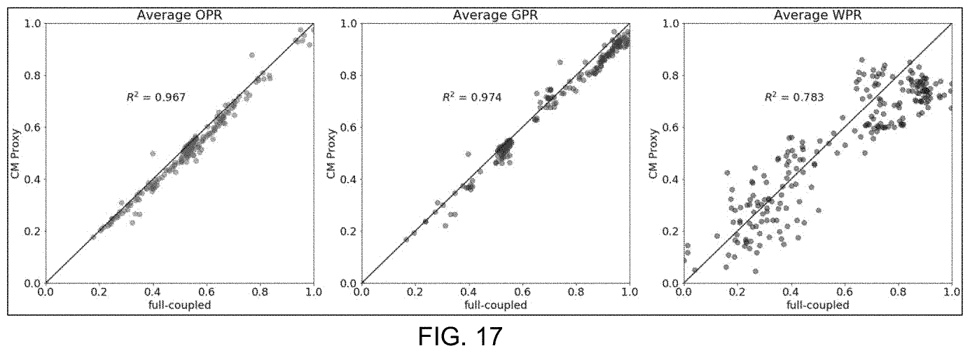

FIG. 17 provides field-level rates comparison from CM Proxy and blind test fully coupled model in Q-Q plot. These rates fall on or nearby the 45° line with R² about 0.97. The absolute value of R² is slightly smaller (as expected) than that of predicting the training case in FIG. 8, but it is still a number indicating very good accuracy. Through this application, it demonstrates that CM Proxy could provide a very good accuracy in predicting perturbed case by incorporating multiple training simulations.

APPLICATION TO OPTIMIZATION PROBLEM: As the CM Proxy demonstrates the capability of reducing the computational time from more than 24 hours down to about 1.5 hours with more than 95% accuracy preserved, it is suitable for a rapid evaluation and optimization of the surface network operation or the drilling sequence. In the following preliminary application, the CM Proxy was applied as the forward simulator to evaluate the coupled model performance to optimize the put-on-production of five groups of wells. The controlling or optimizing parameters are the put-on-production time discretized on the first day of each month, within a window of 7 years. Wells within one group (multiwell pad) start simultaneously, while two groups of wells cannot start at the same time, considering the rig resource constraints.

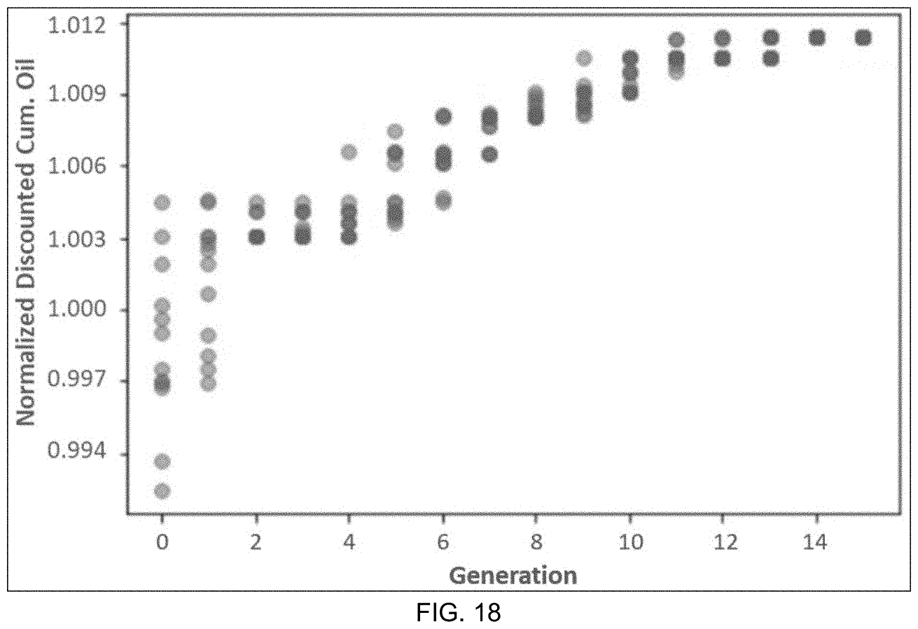

In this application, the discounted cumulative oil production is selected as the objective function. The optimization algorithm is genetic algorithm, with a population size of 12 and a generation number of 15. FIG. 18 presents the discounted cumulative oil (y-axis=1.0 stands for the base case) evolving with generation. The relative improvement is about 1.2%, which seems not notable because of the limited group of wells considered during the optimization. And that improvement corresponds to nearly half-million barrels of oil. The parameters of the selected optimized model using CM proxy are then applied to the fully coupled model, and the incremental cumulative oil production is validated. Note that it takes less than 2 days to finish all the simulations with 5 CM Proxy forward simulations running simultaneously. It might take up to 1 month to finish the same amount of fully coupled model runs even with the same number of concurrent simulations.

The instant disclosure provides a physics-based CM Proxy to facilitate the evaluation of coupled simulation models. The computational expensive subsurface reservoir simulations are replaced by the pretrained IPR database. The surface network model is retained to provide the capability of evaluating different surface network operations. Also provided is the mechanism to handle multiple training simulations to better capture well interference with an intelligent IPR lookup strategy and nonpartitioning grouping. The application of CM Proxy to two super giant fields coupled model reduces the computational time from more than 24 hours to about 1.5 hours with more than 95% accuracy preserved. Its capability is further demonstrated through the application to a preliminary optimization study. A few highlights and lessons learned are summarized below:
1. The computational speedup could be an order of magnitude or more, largely depending on how much portion the surface network simulation takes in fully coupled model simulation. The computation speedup may occur even if the surface network intact is kept intact. The computation time could be further aggressively reduced if the surface network model is also approximated. In the examples provided hereinabove, the surface simulator used a surface network model (also referred to as a surface model) to represent the surface during generation of the performance forecast. However, the surface simulator may use a proxy to represent the surface during generation of the performance forecast. The proxy that may be utilized by the surface simulator may include a table lookup or a neural network.
2. The accuracy of the CM Proxy depends on the difference between the scenarios that the proxy is trained on and the scenarios are evaluated. More specifically, it provides better accuracy with interpolation instead of extrapolation while regenerating IPR curves.
3. The multiple training simulations could enrich the IPR database and thus widen the applicability of CM Proxy. If only a few training simulations are available, Kriging proves to work effectively. More advanced algorithms, such as the ones based on neural networks, may be utilized when hundreds of training simulations are possible.
4. It is important for CM Proxy to implement and honor the FM logic, such as group rate allocation, well prioritizing, and well conditional shut-in. These FM logics represent operator's development policy rather than physical constraints.
5. To improve computation efficiency, examples of the IPR-based CM Proxy discussed herein are applied at the well level and therefore do not directly track pressure and grid/region properties. One skilled in the art will appreciate that further enhancements may be made to capture completion level events and/or handle advanced EOR techniques (e.g., polymer flooding, steam flooding, in-situ combustion, etc.).

More information may also be found in at least the following: Yang, et al. “A Physics-Based Proxy for Surface and Subsurface Coupled Simulation Models.” SPE Journal. Mar. 11, 2022, SPE-204004-PA and Yang, et al. “A Physics-Based Proxy for Surface and Subsurface Coupled Simulation Models.” Paper presented at the SPE Reservoir Simulation Conference, On-Demand, Oct. 19, 2021, SPE-204004-MS, each of which is incorporated by reference.

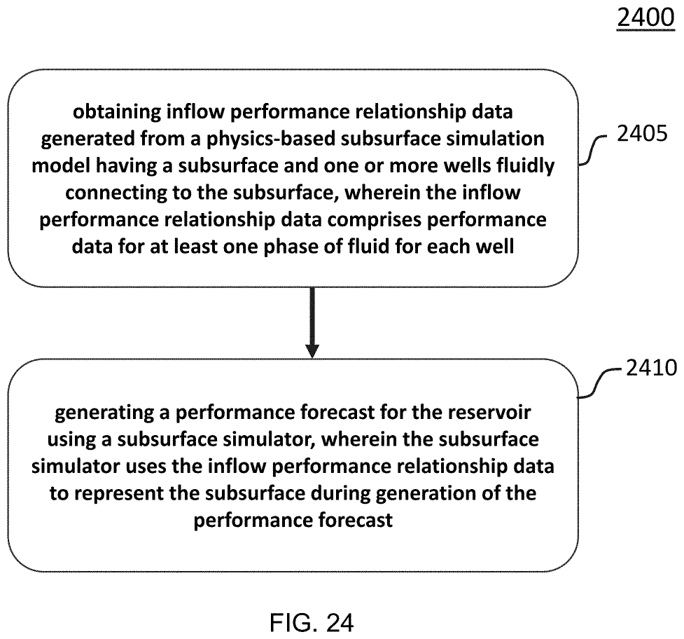

FIG. 24 illustrates another example process 2400 for generating a reservoir performance forecast. The process 2400 of FIG. 24 is similar to the process 2000 of FIG. 20 except that the process 2400 does not utilize a surface simulator. Thus, the process 2400 may be considered a “subsurface simulator only” process. At step 2405, the process 2400 includes obtaining inflow performance relationship data generated from a physics-based subsurface simulation model having a subsurface and one or more wells fluidly connecting to the subsurface. The inflow performance relationship data comprises performance data for at least one phase of fluid for each well. At step 2410, the process 2400 includes generating a performance forecast for the reservoir using a subsurface simulator. The subsurface simulator uses the inflow performance relationship data to represent the subsurface during generation of the performance forecast.

While particular embodiments are described above, it will be understood it is not intended to limit the invention to these particular embodiments. On the contrary, the invention includes alternatives, modifications and equivalents that are within the spirit and scope of the appended claims. Numerous specific details are set forth in order to provide a thorough understanding of the subject matter presented herein. But it will be apparent to one of ordinary skill in the art that the subject matter may be practiced without these specific details. In other instances, well-known methods, procedures, components, and circuits have not been described in detail so as not to unnecessarily obscure aspects of the embodiments.

The terminology used in the description of the invention herein is for the purpose of describing particular embodiments only and is not intended to be limiting of the invention. As used in the description of the invention and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, operations, elements, and/or components, but do not preclude the presence or addition of one or more other features, operations, elements, components, and/or groups thereof.

The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent of the given numeric value provided such a deviation does not alter the end function or result of the value. Therefore, a value of about 1% can be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

Additionally, the following nomenclature and subscripts are utilized herein:

| Nomenclature | Subscript |
|---|---|
| bhp = bottom-hole pressure | g = gas phase |
| cum = cumulative production or injection | i = iterator for timestep |
| f = generic function | o = oil phase |
| q = production or injection rate | p = phase of fluid |
| w1, w2 = weights | w = water phase |

It is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components. For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C. In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C). In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

Unless defined otherwise, all technical and scientific terms used herein have the same meanings as commonly understood by one of skill in the art to which the disclosed invention belongs. All citations referred herein are expressly incorporated by reference.

Although some of the various drawings illustrate a number of logical stages in a particular order, stages that are not order dependent may be reordered and other stages may be combined or broken out. While some reordering or other groupings are specifically mentioned, others will be obvious to those of ordinary skill in the art and so do not present an exhaustive list of alternatives. Moreover, it should be recognized that the stages could be implemented in hardware, firmware, software or any combination thereof.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method of generating a reservoir performance forecast, the method comprising:
obtaining inflow performance relationship data generated from a physics-based subsurface-surface coupled simulation model having a surface, a subsurface, and one or more wells fluidly connecting the subsurface to the surface, wherein the inflow performance relationship data comprises performance data for at least one phase of fluid for each well; and
generating a performance forecast for the reservoir using a subsurface simulator and a surface simulator, wherein the subsurface simulator uses the inflow performance relationship data to represent the subsurface during generation of the performance forecast, and wherein the performance forecast satisfies constraints solved by the surface simulator.

2. The method of claim 1, wherein the at least one phase comprises a gas phase, an oil phase, a water phase, or any combination thereof.

3. The method of claim 1, wherein the inflow performance relationship data for each well is generated as a function of cumulative production, as a function of cumulative injection, as a function of bottom hole pressure, as a function of tubing head pressure, or any combination thereof.

4. The method of claim 1, wherein the inflow performance relationship data for each well is generated using productivity index multiplier data in response to an acid treatment, a fracturing operation, formation damage, rock geomechanics, or any combination thereof.

5. The method of claim 1, wherein the inflow performance relationship data is generated from a single physics-based subsurface-surface coupled simulation model.

6. The method of claim 1, wherein the inflow performance relationship data is generated from multiple physics-based subsurface-surface coupled simulation models.

7. The method of claim 1, wherein generating the performance forecast comprises determining which inflow performance relationship to utilize for each well at each prediction time-step based on the inflow performance relationship data.

8. The method of claim 7, wherein linear interpolation based on cumulative production, cumulative injection, or any combination thereof is utilized at each prediction time-step to determine which inflow performance relationship to utilize for each well.

9. The method of claim 7, wherein the determined inflow performance relationships are truncated in response to flow constraints for each well.

10. The method of claim 9, wherein the flow constraints comprise bottom hole pressure, tubing head pressure, injection rate, production rate, or any combination thereof.

11. The method of claim 7, wherein Kriging or a neural network based on cumulative production, cumulative injection, or any combination thereof from each well and its neighboring wells is utilized at each prediction time-step to determine which inflow performance relationship to utilize for each well.

12. The method of claim 11, wherein the neighboring wells are determined based on user specified criteria.

13. The method of claim 1, further comprising computing a range of pressure points within the inflow performance relationship data for each well to generate the performance forecast.

14. The method of claim 1, wherein the surface simulator solves pressure and rate constraints of equipment on the surface during generation of the performance forecast.

15. The method of claim 14, wherein the surface simulator uses a surface network model to represent the surface during generation of the performance forecast.

16. The method of claim 14, wherein the surface simulator uses a proxy to represent the surface during generation of the performance forecast.

17. The method of claim 16, wherein the proxy used by the surface simulator comprises a table lookup or a neural network.

18. A computer system, comprising:
one or more processors;
memory; and
one or more programs, wherein the one or more programs are stored in the memory and configured to be executed by the one or more processors, the one or more programs including instructions that when executed by the one or more processors cause the system to:
obtain inflow performance relationship data generated from a physics-based subsurface-surface coupled simulation model having a surface, a subsurface, and one or more wells fluidly connecting the subsurface to the surface, wherein the inflow performance relationship data comprises performance data for at least one phase of fluid for each well; and
generate a performance forecast for the reservoir using a subsurface simulator and a surface simulator, wherein the subsurface simulator uses the inflow performance relationship data to represent the subsurface during generation of the performance forecast, and wherein the performance forecast satisfies constraints solved by the surface simulator.

19. A method of generating a reservoir performance forecast, the method comprising:
obtaining inflow performance relationship data generated from a physics-based subsurface simulation model having a subsurface and one or more wells fluidly connecting to the subsurface, wherein the inflow performance relationship data comprises performance data for at least one phase of fluid for each well; and
generating a performance forecast for the reservoir using a subsurface simulator, wherein the subsurface simulator uses the inflow performance relationship data to represent the subsurface during generation of the performance forecast.

20. A computer system, comprising:
one or more processors;
memory; and
one or more programs, wherein the one or more programs are stored in the memory and configured to be executed by the one or more processors, the one or more programs including instructions that when executed by the one or more processors cause the system to:
obtain inflow performance relationship data generated from a physics-based subsurface simulation model having a subsurface and one or more wells fluidly connecting to the subsurface, wherein the inflow performance relationship data comprises performance data for at least one phase of fluid for each well; and
generate a performance forecast for the reservoir using a subsurface simulator, wherein the subsurface simulator uses the inflow performance relationship data to represent the subsurface during generation of the performance forecast.
